(19) United States
(12) Patent Application Publication
(10) Pub. No.: US 2010/0140715 A1
(43) Pub. Date: Jun. 10, 2010

(54) SEMICONDUCTOR DEVICE

(75) Inventors: Kazutoshi Nakamura, Kanagawa-ken (JP); Norio Yasuhara, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/630,018

(22) Filed: Dec. 3, 2009

(30) Foreign Application Priority Data
Dec. 4, 2008 (JP) 2008-310217
Nov. 12, 2009 (JP) 2009-259112

(51) Int. Cl. H01L 27/06

(52) U.S. Cl. 257/368; 257/288; 257/E27.014

(57) ABSTRACT

A semiconductor device includes: a semiconductor region of first conductivity type provided in a semiconductor layer of first conductivity type; a first semiconductor region of second conductivity type; a second semiconductor region of second conductivity type; a third semiconductor region of second conductivity type having a lower impurity concentration than the second semiconductor region of second conductivity type; a first insulating layer provided in the third semiconductor region of second conductivity type; a control electrode provided on the semiconductor region of first conductivity type via a second insulating layer; a first auxiliary electrode provided on the first insulating layer; a first main electrode electrically connected to the first semiconductor region of second conductivity type; and a second main electrode electrically connected to the second semiconductor region of second conductivity type.

### CROSS-REFERENCE TO RELATED APPLICATIONS

This application is based upon and claims the benefit of priority from the prior Japanese Patent Application No. 2008-310217, filed on Dec. 4, 2008 and the prior Japanese Patent Application No. 2009-259112, filed on Nov. 12, 2009; the entire contents of which are incorporated herein by reference.

### BACKGROUND OF THE INVENTION

1. Field of the Invention

This invention relates to a semiconductor device including a structure of a field effect transistor.

2. Background Art

A power supply in a mode of synchronous rectifying is generally used with the decrease of voltage of a power supply used for CPU in a computer and the like. It is required for a power supply to recover the voltage promptly to a steady state on an abrupt change of a load. For that purpose, it is effective to increase a switching frequency. However, increase of the switching frequency causes increase of number of times of switching, thereby a switching loss increases to deteriorate efficiency. Therefore, small capacitance between a gate and a drain of a switching device is required. The capacitance between the gate and the drain is called as “mirror capacitance” and known as a parameter relating to a switching speed and a switching loss.

On the other hand, a power device technology trends toward integrating using a fine process to be a system complex and making its intelligent. When the power device is combined with the fine process, the process is required not to change drastically. In particular, a thermal process has an effect to characteristics of a fine CMOS device, thereby its condition is preferably not to be changed. In a recent fine process, formation of a shallow PN junction rejects receiving a thermal history.

A technique combining the power device without additional process in the fine process is proposed (for example, see “A. Heringa, J. Sonsky, J. Perez-Gonzalez, R. Y. Su and P. Y. Chiang, Proceedings of 20th International Symposium on Power Semiconductor Devices & IC's, pp. 271-274, 2008”).

### SUMMARY OF THE INVENTION

According to an aspect of the invention, there is provided a semiconductor device including: a semiconductor region of first conductivity type provided in a semiconductor layer of first conductivity type; a first semiconductor region of second conductivity type provided in the semiconductor region of first conductivity type; a second semiconductor region of second conductivity type provided in the semiconductor layer of first conductivity type spaced from the semiconductor region of first conductivity type; a third semiconductor region of second conductivity type provided between the semiconductor region of first conductivity type and the second semiconductor region of second conductivity type in the semiconductor layer of first conductivity type, and having a lower impurity concentration than the second semiconductor region of second conductivity type; a first insulating layer provided in the third semiconductor region of second conductivity type; a control electrode provided on the semiconductor region of first conductivity type arranged between the first semiconductor region of second conductivity type and the third semiconductor region of second conductivity type via a second insulating layer; a first auxiliary electrode provided on the first insulating layer spaced from the control electrode; a first main electrode electrically connected to the first semiconductor region of second conductivity type; and a second main electrode electrically connected to the second semiconductor region of second conductivity type, when a direction substantially parallel to a direction of a main current flowing between the first semiconductor region of second conductivity type and the second semiconductor region of second conductivity type being defined as a first direction, and a direction substantially perpendicular to the first direction and substantially parallel to a major surface of the semiconductor layer of first conductivity type being defined as a second direction, most part of the first insulating layer having a width along the second direction substantially narrowing from the control electrode toward the second main electrode.

According to another aspect of the invention, there is provided a semiconductor device including: a semiconductor region of first conductivity type provided in a semiconductor layer of first conductivity type; a first semiconductor region of second conductivity type provided in the semiconductor region of first conductivity type; a second semiconductor region of second conductivity type provided in the semiconductor layer of first conductivity type spaced from the semiconductor region of first conductivity type; a third semiconductor region of second conductivity type provided between the semiconductor region of first conductivity type and the second semiconductor region of second conductivity type in the semiconductor layer of first conductivity type, and having a lower impurity concentration than the second semiconductor region of second conductivity type; a first insulating layer provided in the third semiconductor region of second conductivity type; a control electrode provided on the semiconductor region of first conductivity type arranged between the first semiconductor region of second conductivity type and the third semiconductor region of second conductivity type via a second insulating layer; a first auxiliary electrode provided on the first insulating layer spaced from the control electrode; at least one second auxiliary electrode provided on the first insulating layer spaced from the first auxiliary electrode; a first main electrode electrically connected to the first semiconductor region of second conductivity type; and a second main electrode electrically connected to the second semiconductor region of second conductivity type.

### BRIEF DESCRIPTION OF THE DRAWINGS

FIG. 1 is a schematic plan view illustrating the configuration of a semiconductor device according to a first embodiment of the invention;

FIG. 2 is a cross-sectional view along A-A′ line of the semiconductor device shown in FIG. 1;

FIG. 3 is a cross-sectional view along B-B′ line of the semiconductor device shown in FIG. 1;

FIG. 4 is a cross-sectional view along C-C′ line of the semiconductor device shown in FIG. 1;

FIG. 5 is a schematic view showing the configuration of a field effect transistor of a comparative example;

FIG. 6 is a cross-sectional view along A-A′ line of a semiconductor device according to a second embodiment of the invention;

FIG. 7 is a cross-sectional view along C-C′ line of the semiconductor device shown in FIG. 6;

FIG. 8 is a schematic plan view illustrating the configuration of a semiconductor device according to a third embodiment of the invention;

FIG. 9 is a cross-sectional view along A-A′ line of the semiconductor device shown in FIG. 8;

FIG. 10 is a schematic plan view illustrating the configuration of a semiconductor device according to a fourth embodiment of the invention;

FIG. 11 is a cross-sectional view along A-A′ line of the semiconductor device shown in FIG. 10;

FIG. 12 is a schematic plan view illustrating the configuration of a semiconductor device according to a fifth embodiment of the invention;

FIG. 13 is a cross-sectional view along A-A′ line of the semiconductor device shown in FIG. 12;

FIG. 14 is a schematic plan view illustrating the configuration of a semiconductor device according to a sixth embodiment of the invention;

FIG. 15 is a cross-sectional view along A-A′ line of the semiconductor device shown in FIG. 14;

FIG. 16 is a schematic plan view illustrating the configuration of a semiconductor device according to a seventh embodiment of the invention;

FIG. 17 is a cross-sectional view along A-A′ line of the semiconductor device shown in FIG. 16;

FIGS. 18A and 18B are schematic views of a switching power supply based on the semiconductor device of the invention;

FIGS. 19A and 1913 are schematic views of a switching power supply based on another semiconductor device of the invention;

FIG. 20 is a schematic plan view illustrating the configuration of a semiconductor device according to a eighth embodiment of the invention;

FIG. 21 is a cross-sectional view along C-C′ line of the semiconductor device shown in FIG. 20; and

FIG. 22 is a schematic plan view illustrating the configuration of a semiconductor device according to an ninth embodiment of the invention.

### DETAILED DESCRIPTION OF THE INVENTION

Embodiments of the invention will now be described with reference to the drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described previously with reference to earlier drawings are marked with like reference numerals, and a detailed description is omitted as appropriate.

### First Embodiment

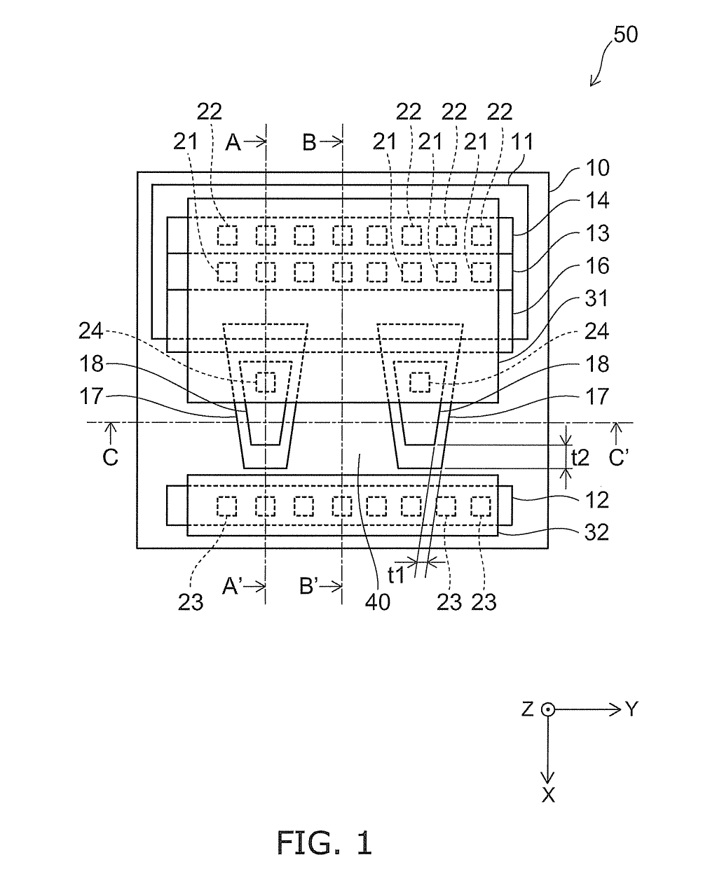

FIGS. 1 to 4 are schematic views illustrating the configuration of a semiconductor device according to a first embodiment of the invention.

FIG. 1 is a schematic plan view illustrating the configuration of the semiconductor device according to the first embodiment of the invention.

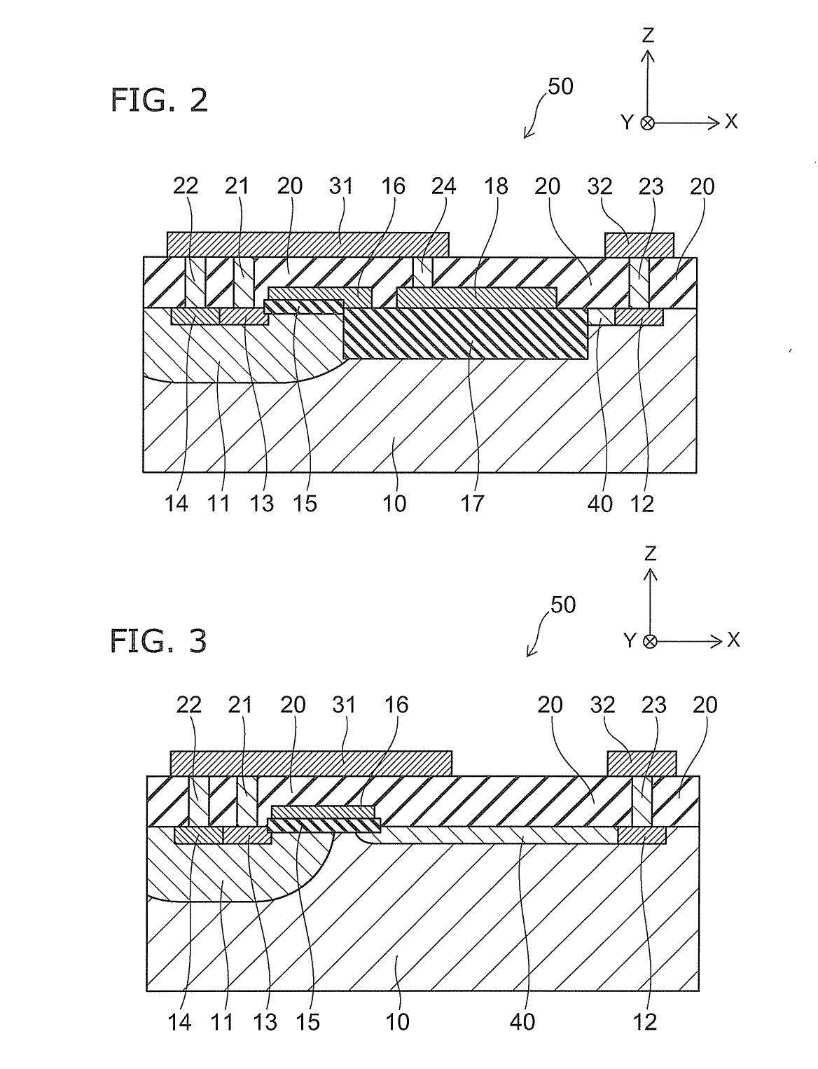

FIG. 2 is a cross-sectional view along A-A′ line of the semiconductor device shown in FIG. 1.

FIG. 3 is a cross-sectional view along B-B′ line of the semiconductor device shown in FIG. 1.

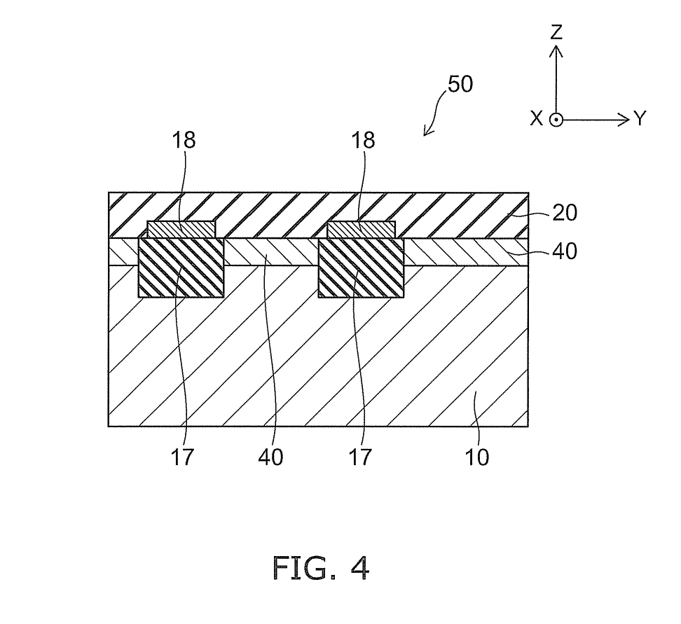

FIG. 4 is a cross-sectional view along C-C′ line of the semiconductor device shown in FIG. 1.

As shown in FIGS. 1 to 4, a plane parallel to a major surface of a p-type semiconductor substrate 10 (semiconductor layer of first conductivity type) is set to be an X-Y plane, and a direction perpendicular to the X-Y plane is set to be a Z-axis. A direction of the A-A′ line shown in FIG. 1 is set to be an X-axis, and a direction perpendicular to the Z-axis and X-axis is set to be a Y-axis.

Here, in the plan view, a portion essentially unseen by an insulating layer is also shown with a solid line.

The semiconductor device 50 according to the first embodiment of the invention is MOSFET.

The semiconductor device 50 includes a p well region 11 (semiconductor region of first conductivity type) provided in the p-type semiconductor substrate 10 (semiconductor layer of first conductivity type). The p well region 11 (semiconductor region of first conductivity type) has a larger impurity concentration than the p-type semiconductor substrate 10 (semiconductor layer of first conductivity type), and the amount of impurity dose in the p-well region 11 (semiconductor region of first conductivity type) is illustratively 1×10¹³ to 1×10¹⁴/cm².

An n⁺ drain region 12 (second semiconductor region of second conductivity type) is provided spaced from the p well region 11 (semiconductor region of first conductivity type) in the p-type semiconductor substrate 10 (semiconductor layer of first conductivity type). An n⁺ source region 13 (first semiconductor region of second conductivity type) is provided in the p well region 11 (semiconductor region of first conductivity type). Here, the n⁺ drain region 12 (second semiconductor region of second conductivity type) and the n⁺ source region 13 (first semiconductor region of second conductivity type) have illustratively the amount of impurity dose of 1×10¹⁵/cm² or more.

An n⁻ drift region 40 (third semiconductor region of second conductivity type) is provided between the p well 11 (semiconductor region of first conductivity type) and n⁺ drain region 12 (second semiconductor region of second conductivity type) in the p-type semiconductor substrate 10 (semiconductor layer of first conductivity type).

The n⁻ drift region 40 (third semiconductor region of second conductivity type) has a smaller impurity concentration than the n⁺ drain region 12 (second semiconductor region of second conductivity type) and the n⁺ source region 13 (first semiconductor region of second conductivity type), and the amount of impurity dose in the n⁻ drift region 40 (third semiconductor region of second conductivity type) is illustratively 2×10¹² to 6×10¹²/cm².

A gate electrode 16 (control electrode) is provided between the n⁺ source region 13 (first semiconductor region of second conductivity type) and the n⁻ drift region 40 (third semiconductor region of second conductivity type) via a gate oxide film 15 (second insulating layer), for example, SiO₂.

An STI (Shallow Trench Isolation) 17 (first insulating layer) is illustratively buried with SiO₂ so as to penetrate the n⁻ drift region 40 (third semiconductor region of second conductivity type) and extend to the p-type semiconductor substrate 10 (semiconductor layer of first conductivity type). Here, in the p-type semiconductor substrate 10 (semiconductor layer of first conductivity type), a direction substantially parallel to a direction of a main current passing through between the n⁺ source region 13 (first semiconductor region of second conductivity type) and the n⁺ drain region 12 (second semiconductor region of second conductivity type) is defined as a first direction, and a direction substantially perpendicular to the first direction and substantially parallel to a main surface of the p-type semiconductor substrate 10 (semiconductor layer of first conductivity type) is defined as a second direction. An X direction shown in FIG. 1 is the first direction and a Y direction is the second direction.

Then, most part of the STI 17 (first insulating layer) has a width along the Y direction (second direction) narrowing along a direction from the gate electrode 16 (control electrode) toward the n⁺ drain region 12 (second semiconductor region of second conductivity type). Here, the most part of the STI 17 (first insulating layer) means illustratively a portion except an end portion of the n⁺ source region 13 (first semiconductor region of second conductivity type) side. The reason is that the end portion of the STI 17 (first insulating layer) of the n⁺ source region 13 (first semiconductor region of second conductivity type) side may have a round (or a bulge) toward the n⁺ source region 13 (first semiconductor region of second conductivity type) side, and thus may have no substantially narrowing width along the Y direction (second direction).

Here, as shown in FIG. 1, the semiconductor device 50 according to this embodiment is illustrated as the case where two STIs 17 (first insulating layer) are provided. However the invention is not limited thereto. One or more STI (first insulating layer) can be provided and can have a striped configuration in the Y direction (second direction).

A field plate electrode 18 (first auxiliary electrode) is provided spaced from the gate electrode 16 (control electrode) on the STI 17 (first insulating layer). Its shape is preferably such that the width along the Y direction (second direction) is narrowing along a direction from the gate electrode 16 (control electrode) toward the n⁺ drain region 12 (second semiconductor region of second conductivity type). When the width along the Y direction (second direction) is not narrowing, for example, constant, the gate electrode 16 (control electrode) side of the n⁻ drift region 40 (third semiconductor region of second conductivity type) is resistant to depletion. Therefore, an electric field between the gate electrode 16 (control electrode) and the n⁻ drift region 40 (third semiconductor region of second conductivity type) increases to cause a decrease of breakdown voltage.

Furthermore, with regard to a space between the field plate electrode 18 (first auxiliary electrode) and the n⁻ drift region 40 (third semiconductor region of second conductivity type), as shown in FIG. 1, when the space along the Y direction (second direction) is assumed to be t1, and the space on the n⁺ drain region 12 (second semiconductor region of second conductivity type) side in the X direction (first direction) is assumed to be t2, t1<t2 is preferred.

Thereby, the STI 17 (first insulating layer) between the field plate electrode 18 (first auxiliary electrode) and the n⁺ drain region 12 (second semiconductor region of second conductivity type) is allowed to be enlarged toward the n⁺ drain region 12 (second semiconductor region of second conductivity type).

A p⁺ contact region 14 being in contact with the p well region 11 (semiconductor region of first conductivity type) is provided in adjacent to the n⁺ source region 13 (first semiconductor region of second conductivity type) in the p well region 11 (semiconductor region of first conductivity type). Here, the p⁺ contact region has a larger impurity concentration than p well region 11 (semiconductor region of first conductivity type), and the amount of impurity dose in the p⁺ contact region is, for example, 1×10¹⁵/cm² or more.

A source electrode 31 (first main electrode) is electrically connected to each of the n⁺ source region 13 (first semiconductor region of second conductivity type) and the p⁺ contact region 14 via a contact plug 21 and a contact plug 22. A drain electrode 32 (second main electrode) is electrically connected to the n⁺ drain region 12 (second semiconductor region of second conductivity type) via a contact plug 23. Furthermore, the source electrode 31 (first main electrode) is electrically connected to the field plate electrode 18 (first auxiliary electrode) via a via plug 24.

As mentioned above, the semiconductor device 50 of the example is manufacturable by a manufacturing process of CMOS. Moreover, the field plate electrode 18 (first auxiliary electrode) is connected to the source electrode 31 (first main electrode) without connecting to the gate electrode 16 (control electrode).

Therefore, according to the semiconductor device 50 of the example, a semiconductor device of a field effect transistor with reduced capacitance between the gate and the drain and between the gate and the source, and being susceptible to combination with the fine process comes to be manufacturable.

Here, the example illustrates formation of MOSFET, however, the invention is not limited to therein, and the semiconductor device of the invention includes also those having a plurality of MOSFET and other CMOS elements formed on the same substrate.

### Comparative Example

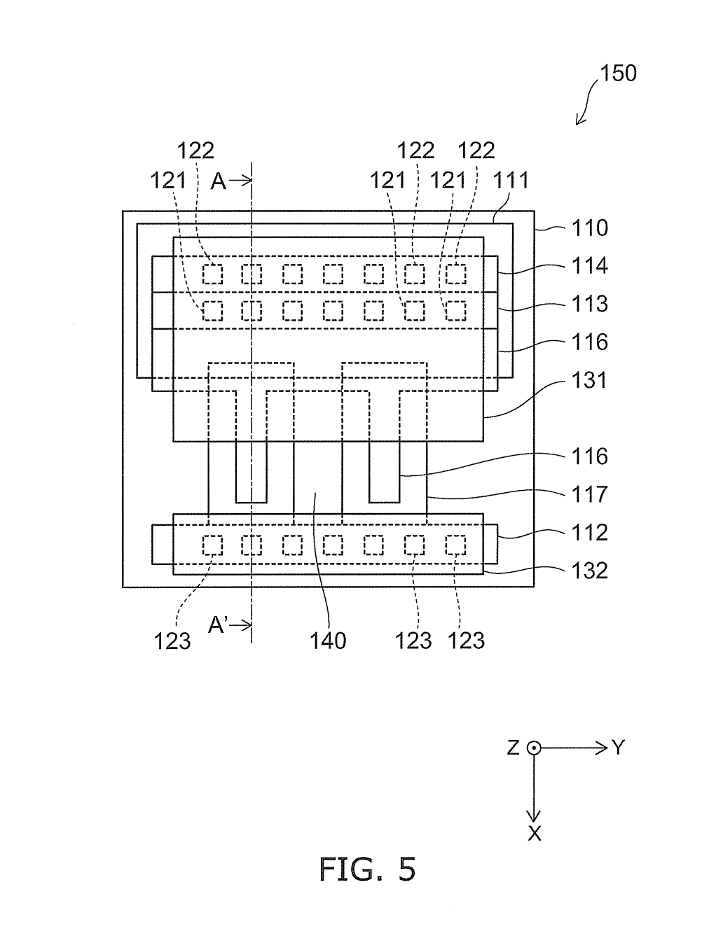

FIG. 5 is a schematic view showing the configuration of a field effect transistor of a comparative example.

As shown in FIG. 5, a plane parallel to a major surface of a p-type semiconductor substrate 110 is set to be an X-Y plane, and a direction perpendicular to the X-Y plane is set to be a Z-axis. A direction of the A-A′ line shown in FIG. 5 is set to be an X-axis, and a direction perpendicular to the Z-axis and X-axis is set to be a Y-axis.

Here, in the plan view, a portion essentially unseen by an insulating layer is also shown with a solid line.

As shown in FIG. 5, the field effect transistor 150 of the comparative example is provided with a p well region 111 in the p-type semiconductor substrate 110. An n⁺ drain region 112 is provided spaced from the p well region 11 in the p-type semiconductor substrate 110. An n⁺ source region 113 is provided in the p well region 111.

An n⁻ gate electrode 116 is provided between the n⁺ drain region 112 and the n⁺ source region 113 via a gate oxide film not shown. An n⁻ drift region 140 is provided between the gate electrode 116 and the n⁺ drain region 112. An STI 117 is provided on the n⁻ drift region 140 in a striped configuration in the Y direction.

The gate electrode 116 is also provided on the STI 117.

A p⁺ contact region 114 being in contact with the p well region 111 is provided in adjacent to the n⁺ source region 113 in the p well region 111. The n⁺ source region 113, the n⁺ drain region 112 and the p⁺ contact region 114 are parallel to each other and extending in the Y direction.

A source electrode 131 is electrically connected to each of the n⁺ source region 113 and the p⁺ contact region 114 via a contact plug 121, a contact plug 122. Moreover, a drain electrode 132 is electrically connected to the n⁺ drain region 112 via a contact plug 123.

As mentioned above, the field effect transistor 150 of the comparative example is manufacturable by a manufacturing process of CMOS. A distinct feature is that the STI 117 is formed in a striped configuration on the n− drift region 140 and the gate electrode 116 is also disposed on the STI 117. The gate electrode 116 disposed on the STI 117 accelerates high depletion in the n− drift region 140 and increases the breakdown voltage as compared with the structure without the STI 117.

However, the gate electrode 116 hangs over largely toward the drain electrode 132, hence the capacitance between the gate and the drain and the capacitance between the gate and the source are large. This increases the switching loss and results in growing a drive loss. Therefore, the goal of the integration of power devices without addition of CMOS processes is achieved, but a problem of unapplicability to high speed switching is remained.

On the contrary, the semiconductor device 50 of the example is manufacturable by the manufacturing process of CMOS, and easy to be combined with the fine process. The field plate electrode 18 (first auxiliary electrode) is not connected to the gate electrode 16 (control electrode), but connected to the source electrode 31 (first main electrode). Therefore, the semiconductor device 50 is a device of a field effect transistor with the reduced capacitance between the gate and the drain and between the gate and the source, and usable for high speed switching and power application.

Furthermore, the STI 17 (first insulating layer) has the width along the Y direction (second direction) narrowing toward the n⁺ drain region 12 (second semiconductor region of second conductivity type) in the X direction (first direction). This allows effective impurity amount contained in the n⁻ drift region 40 (third semiconductor region of second conductivity type) to increase toward the n⁺ drain region 12 (second semiconductor region of second conductivity type) and causes to generate the uniform electric field.

It is known that when a large current flows through the n⁻ drift region 40 (third semiconductor region of second conductivity type), Kirk effect strengthens intensity of the electric field at the boundary between the n⁻ drift region 40 (third semiconductor region of second conductivity type) and the n⁺ drain region 12 (second semiconductor region of second conductivity type) and avalanche occurs. Like the example, increasing the effective impurity amount contained in the n⁻ drift region 40 (third semiconductor region of second conductivity type) toward the n⁺ drain region 12 (second semiconductor region of second conductivity type) causes to suppress the occurrence of Kirk effect and allows the breakdown voltage to increase on flowing of the large current through the n⁻ drift region 40 (third semiconductor region of second conductivity type).

In FIG. 2, the STI 17 (first insulating layer) is not in contact with the n⁺ drain region 12 (second semiconductor region of second conductivity type). Hence, a great amount of effective impurity is contained in the n⁻ drift region 40 (third semiconductor region of second conductivity type), because the STI 17 (first insulating layer) is not provided. This region is resistant to depletion, but the Kirk effect is effectively suppressed by the great amount of effective impurity. The STI 17 (first insulating layer) may be formed with being in contact with the n⁺ drain region 12 (second semiconductor region of second conductivity type) for application of the case where the drain current density is not high.

In the example, the shape of the field plate electrode 18 (first auxiliary electrode) has a width along the Y direction (second direction) narrowing toward the n⁺ drain region 12 (second semiconductor region of second conductivity type) also.

An electric field between the field plate electrode 18 (first auxiliary electrode) and the n⁺ drain region 12 (second semiconductor region of second conductivity type) is easy to increase, thus the electric field is reduced by disposing the STI 17 (first insulating layer) between the field plate electrode 18 (first auxiliary electrode) and the n⁺ drain region 12 (second semiconductor region of second conductivity type). This allows the breakdown voltage to increase on flowing of the large current through the n⁻ drift region 40 (third semiconductor region of second conductivity type).

Furthermore, as shown in FIG. 1, with regard to a space between the field plate electrode 18 (first auxiliary electrode) and the n⁻ drift region 40 (third semiconductor region of second conductivity type), when the space along the Y direction (second direction) is assumed to be t1, and the space on the n⁺ drain region 12 (second semiconductor region of second conductivity type) side in the X direction (first direction) is assumed to be t2, t1<t2 is preferred. The electric field is allowed to be reduced by enlarging the size of the STI 17 (first insulating layer) between the field plate electrode 18 (first auxiliary electrode) and the n⁺ drain region 12 (second semiconductor region of second conductivity type) toward the n⁺ drain region 12 (second semiconductor region of second conductivity type). This allows the breakdown voltage to be further increased.

By the way, the gate electrode 16 (control electrode) and the STI 17 (first insulating layer) intersect in the semiconductor device 50. When voltage higher than a threshold is applied to the gate electrode 16 (control electrode), a channel occurring immediately under the gate electrode 16 (control electrode) does not operate effectively in a region where the gate electrode 16 (control electrode) and the STI 17 (first insulating layer) intersect, because the STI 17 (first insulating layer) is placed in the direction of current flow. This causes the channel resistance to increase and the whole ON resistance to be raised.

Next, an example with improvement of this point is described.

### Second Embodiment

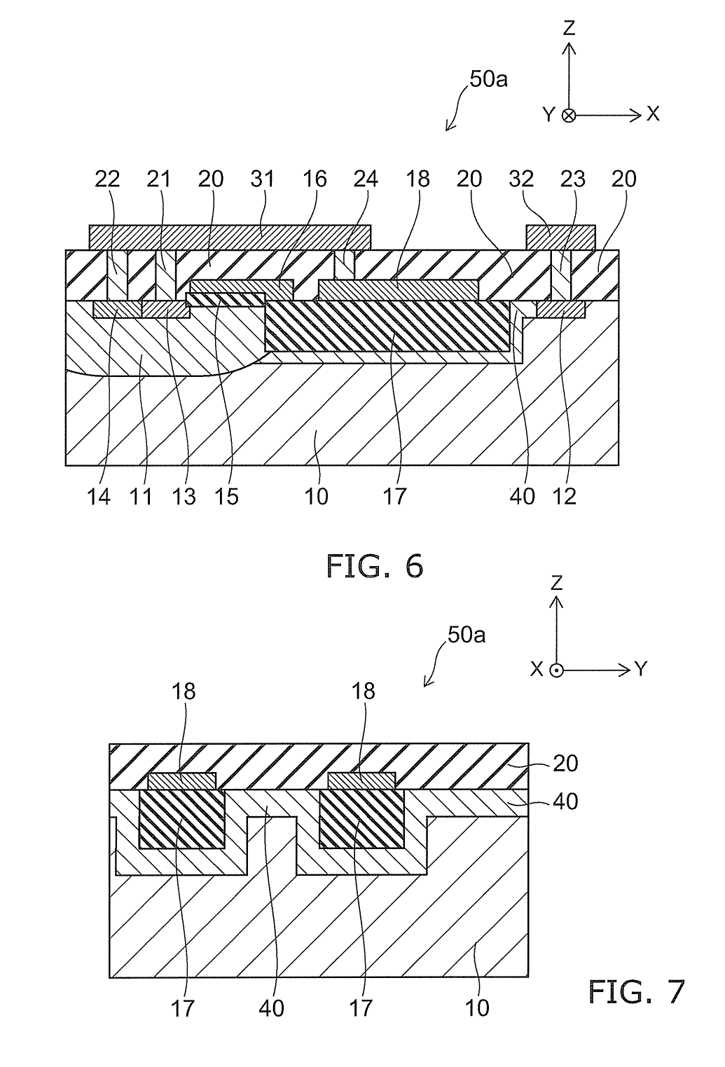

FIGS. 6 and 7 are schematic views illustrating the configuration of a semiconductor device according to the second embodiment of the invention.

A plan view of the semiconductor device 50a shown in FIGS. 6 and 7 is the same as the plan view of the semiconductor device 50 shown in FIG. 1. FIG. 6 shows a cross-sectional view along A-A′ line of the semiconductor device 50a. FIG. 7 shows a cross-sectional view along C-C′ line of the semiconductor device 50a. A cross-sectional view along B-B′ line of the semiconductor device 50a is the same as the cross-sectional view of the semiconductor device 50 shown in FIG. 3

The semiconductor device 50a is provided with the n⁻ drift region 40 (third semiconductor region of second conductivity type) not only on the upper surface of the p-type semiconductor substrate 10 (semiconductor layer of first conductivity type) but also on a side wall and a bottom of the STI 17 (first insulating layer). The result other than this is the same as the semiconductor device 50, and hence the description thereof is omitted.

The semiconductor device 50a is provided with the n⁻ drift region 40 (third semiconductor region of second conductivity type) not only on the upper surface of the p-type semiconductor substrate 10 (semiconductor layer of first conductivity type) but also on the side wall and the bottom of the STI 17 (first insulating layer). Thereby, the semiconductor device 50a has the larger sectional area of the n⁻ drift region 40 (third semiconductor region of second conductivity type) than the semiconductor device 50. This causes the resistance of the n⁻ drift region 40 (third semiconductor region of second conductivity type) and the ON resistance to decrease.

When voltage is applied between the drain electrode 32 (second main electrode) and the source electrode 31 (first main electrode) in the OFF state, the n⁻ drift region 40 (third semiconductor region of second conductivity type) provided on the side wall and the bottom of the STI 17 (first insulating layer) is depleted by the electric field between the field plate electrode 18 (first auxiliary electrode) and the p-type semiconductor substrate 10 (semiconductor layer of first conductivity type), and then the breakdown voltage is ensured.

Embodiments of the invention will now be described with the configuration of the n⁻ drift region 40 (third semiconductor region of second conductivity type) provided on the upper surface of the p-type semiconductor substrate 10 (semiconductor layer of first conductivity type). However, also with regard to embodiments of the invention described below, the n⁻ drift region 40 (third semiconductor region of second conductivity type) may be provided on the side wall and the bottom of the STI 17 (first insulating layer).

### Third Embodiment

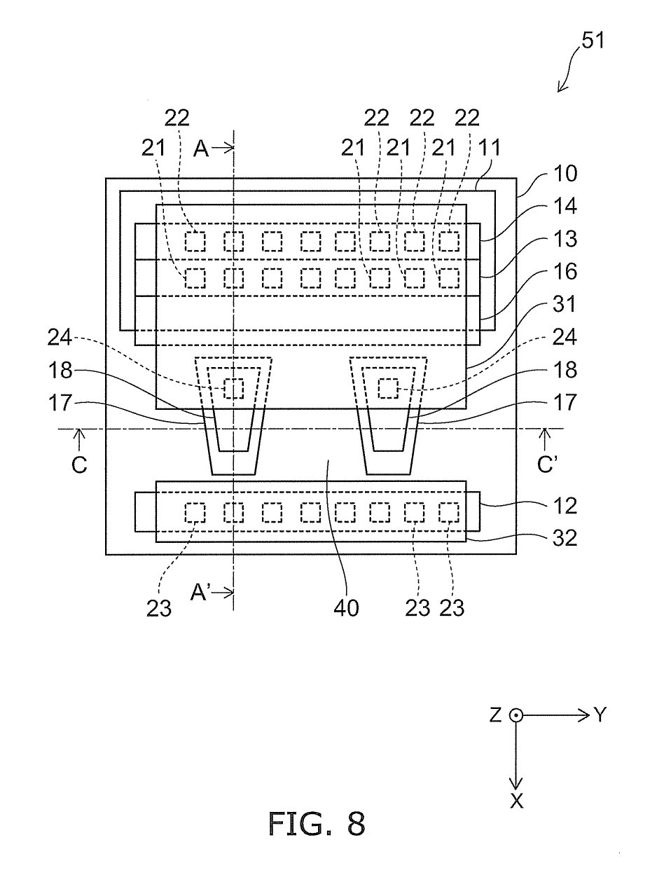

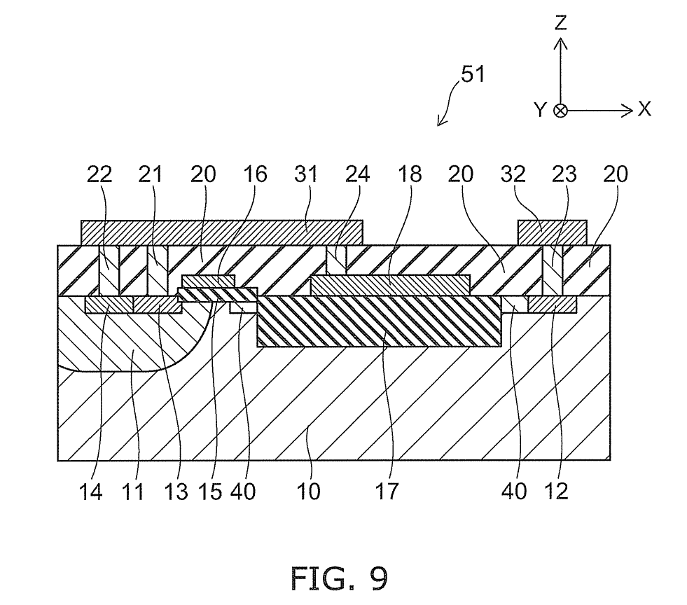

FIGS. 8 and 9 are schematic views illustrating the configuration of a semiconductor device according to a third embodiment of the invention.

FIG. 8 is a schematic plan view illustrating the configuration of the semiconductor device according to the third embodiment of the invention.

FIG. 9 is a cross-sectional view along A-A′ line of the semiconductor device shown in FIG. 8.

As shown in FIGS. 8 and 9, a plane parallel to a major surface of a p-type semiconductor substrate 10 (semiconductor layer of first conductivity type) is set to be an X-Y plane, and a direction perpendicular to the X-Y plane is set to be a Z-axis. A direction of the A-A′ line shown in FIG. 8 is set to be an X-axis, and a direction perpendicular to the Z-axis and X-axis is set to be a Y-axis.

Here, in the plan view, a portion essentially unseen by an insulating layer is also shown with a solid line.

The semiconductor device 51 according to the third embodiment of the invention is MOSFET.

The semiconductor device 51 is provided with the n⁻ drift region 40 (third semiconductor region of second conductivity type) between the gate electrode 16 (control electrode) and the STI 17 (first insulating layer). The result other than this is the same as the semiconductor device 50, and hence the description thereof is omitted.

The semiconductor device 51 is provided with the n⁻ drift region 40 (third semiconductor region of second conductivity type) between the gate electrode 16 (control electrode) and the STI 17 (first insulating layer). Thereby, in the all channels occurring immediately under the gate electrode 16 (control electrode), first, the current flows through the n⁻ drift region 40 (third semiconductor region of second conductivity type), and then flows into the n⁺ drain region 12 (second semiconductor region of second conductivity type) through the n⁻ drift region 40 (third semiconductor region of second conductivity type) between the STIs 17 (first insulating layer).

Thus, all channels operation is effective and On resistance is decreased.

### Forth Embodiment

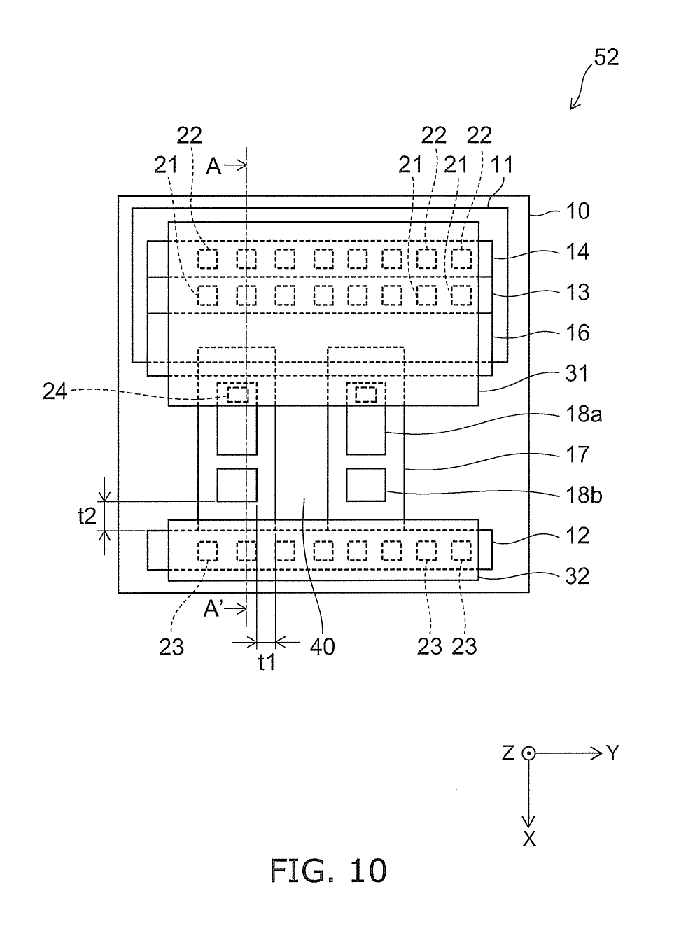

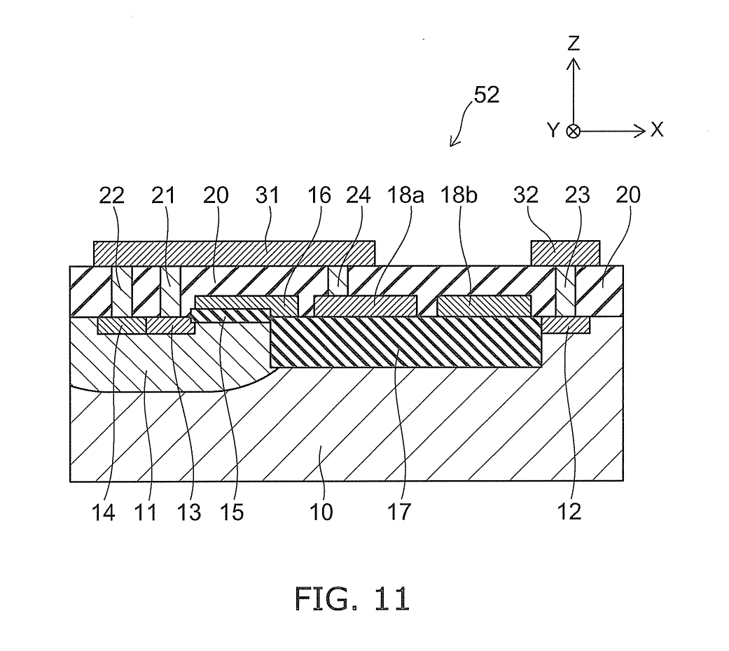

FIGS. 10 and 11 are schematic views illustrating the configuration of a semiconductor device according to a fourth embodiment of the invention.

FIG. 10 is a schematic plan view illustrating the configuration of the semiconductor device according to the fourth embodiment of the invention.

FIG. 11 is a cross-sectional view along A-A′ line of the semiconductor device shown in FIG. 10.

As shown in FIGS. 10 and 11, a plane parallel to a major surface of a p-type semiconductor substrate 10 (semiconductor layer of first conductivity type) is set to be an X-Y plane, and a direction perpendicular to the X-Y plane is set to be a Z-axis. A direction of the A-A′ line shown in FIG. 10 is set to be an X-axis, and a direction perpendicular to the Z-axis and X-axis is set to be a Y-axis.

Here, in the plan view, a portion essentially unseen by an insulating layer is also shown with a solid line.

The semiconductor device 52 according to the fourth embodiment of the invention is MOSFET.

In the semiconductor device 52, the STI 17 (first insulating layer) is in contact with the n⁺ drain region 12 (second semiconductor region of second conductivity type), and the width along the Y direction is constant in the shape. A plurality of field plate electrodes 18a (first auxiliary electrode) and field plate electrodes 18b (second auxiliary electrode) are provided on each of the STIs 17 (first insulating layer). The rest other than this is the same as the semiconductor device 50, and hence the description is omitted.

In the semiconductor device 50, the electric field between the field plate electrode 18 (first auxiliary electrode) and the n⁺ drain region 12 (second semiconductor region of second conductivity type) is easy to increase. Consequently, in the semiconductor device 52, the electric field is reduced by disposing the STI 17 (first insulating layer) between the field plate electrode 18a (first auxiliary electrode) and the n⁺ drain region 12 (second semiconductor region of second conductivity type).

In the semiconductor device 52 shown in FIGS. 10 and 11, the field plate electrode 18a (first auxiliary electrode) is electrically connected to the source electrode 31 (first main electrode) through the via plug 24, and the field plate electrode 18b (second auxiliary electrode) is insulated from all other electrodes. Therefore, potential of the field plate electrode 18b (second auxiliary electrode) is given by a voltage value defined by electrostatic capacitance between each of the source electrode 31 (first main electrode), the drain electrode 32 (second main electrode) and the field plate electrode 18a (first auxiliary electrode) and the field plate electrode 18b (second auxiliary electrode).

Thereby, in an OFF state where voltage less than the threshold voltage is applied to the gate electrode 16 (control electrode), the potential of the field plate electrode 18b (second auxiliary electrode) is intermediate potential between the potential of the drain electrode 32 (second main electrode) and the potential of the field plate electrode 18a (first auxiliary electrode). Therefore, an electric field is applied to the n⁻ drift region 40 (third semiconductor region of second conductivity type) from the gate electrode 16 (control electrode) and the field plate electrode 18b (second auxiliary electrode), and depletion is accelerated in the n⁻ drift region 40 (third semiconductor region of second conductivity type) and the breakdown voltage is increased.

Moreover, the voltage between the field plate electrode 18b (second auxiliary electrode) and the n⁺ drain region 12 (second semiconductor region of second conductivity type) drops as compared with the semiconductor device 50, hence the electric field is reduced and the breakdown voltage is susceptible to be ensured. The field plate electrode 18a (first auxiliary electrode) and 18b (second auxiliary electrode) are not connected to the gate electrode 16 (control electrode), and hence the capacitance between the gate and the drain is reduced and the capacitance between the gate and the source is reduced as compared with the field effect transistor 150 of the comparative example.

### Fifth Embodiment

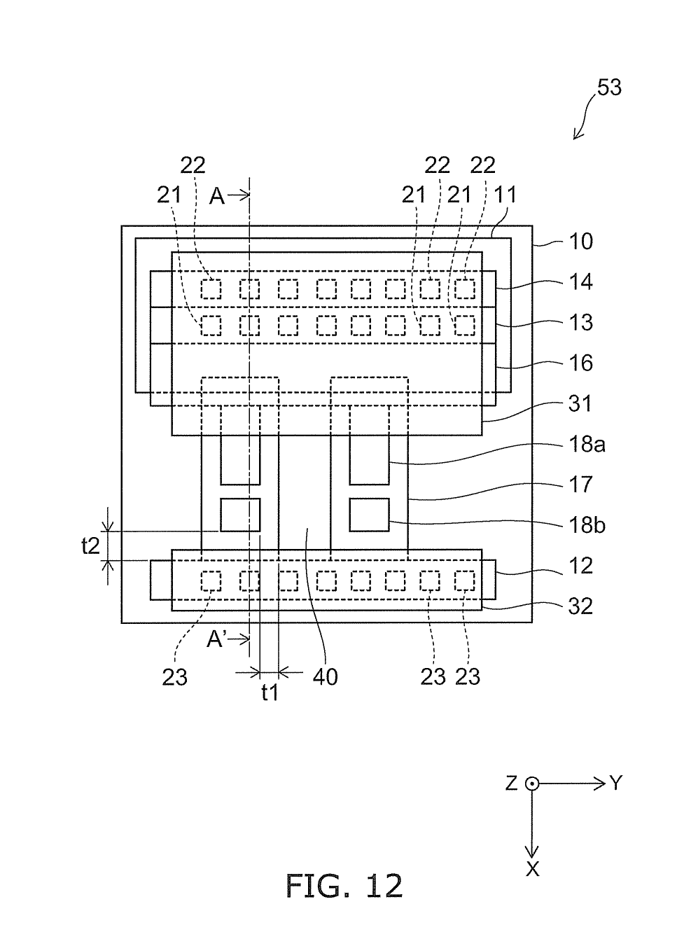

As shown in FIG. 12, the field plate electrode 18a (first auxiliary electrode) is also electrically connected to the gate electrode 16 (control electrode).

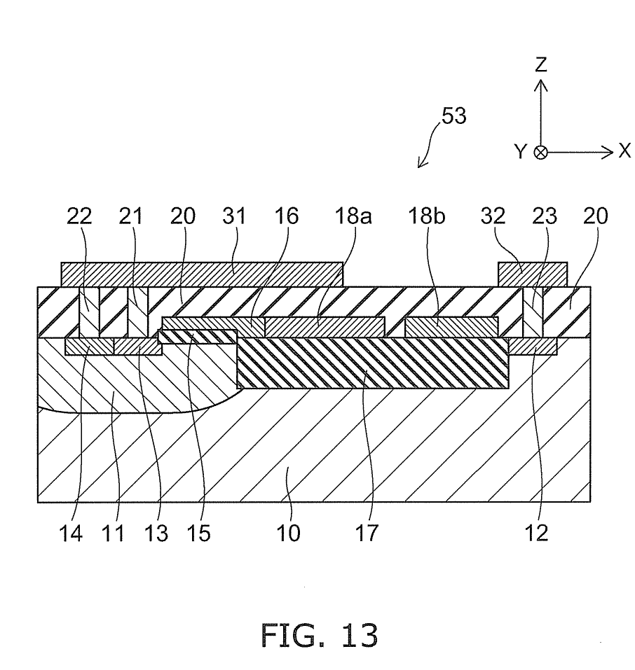

FIG. 13 is a cross-sectional view along A-A′ line of the semiconductor device shown in FIG. 12.

As shown in FIGS. 12 and 13, a semiconductor device 53 according to a fifth embodiment of the invention has the field plate electrode 18a (first auxiliary electrode) of which a length in the X direction is shorter than the STI 17 (first insulating layer), and the field plate electrode 18b (second auxiliary electrode) is electrically insulated from gate electrode 16 (control electrode), and hence the capacitance between the gate and the drain and the capacitance between the gate and the source are reduced as compared with the field effect transistor 150 of the comparative example.

The field plate electrode 18b (second auxiliary electrode) can also be electrically connected to the drain electrode 32 (second main electrode). When the impurity concentration in the n⁻ drift region 40 (third semiconductor region of second conductivity type) is set to be low, the region 40 is depleted by low voltage in the OFF state. Then the electric field is concentrated at the end of the n⁺ drain region 12 (second semiconductor region of second conductivity type) having a shallow junction depth. The field plate electrode 18b (second auxiliary electrode) has the same potential as the drain electrode 32 (second main electrode), thereby the electric field at the end of the n⁺ drain region 12 (second semiconductor region of second conductivity type) is reduced and the breakdown voltage is susceptible to be ensured.

Moreover, the field plate electrode 18b (second auxiliary electrode) has a shorter length in the X direction than the STI 17 (first insulating layer), and is electrically insulated from the field plate electrode 18a (first auxiliary electrode), and hence the capacitance between the gate and the drain and the capacitance between the gate and the source are reduced as compared with the field effect transistor 150 of the comparative example.

Furthermore, also in the semiconductor device 53 of the example and the semiconductor device 52 mentioned above, similar to the semiconductor device 50, it is preferred that the width along the Y direction (second direction) of the STI 17 (first insulating layer) is narrowing toward the n⁺ drain region 12 (second semiconductor region of second conductivity type). It is preferred that the widths along the Y direction (second direction) of the field plate electrode 18a (first auxiliary electrode) and 18b (second auxiliary electrode) are narrowing toward the n⁺ drain region 12 (second semiconductor region of second conductivity type). When the widths along the Y direction (second direction) are not narrowing, for example, are constant, the gate electrode 16 (control electrode) side of the n⁻ drift region 40 (third semiconductor region of second conductivity type) is resistant to the depletion. Therefore, the electric field between the gate electrode 16 (control electrode) and the n⁻ drift region 40 (third semiconductor region of second conductivity type) increases and the breakdown voltage is lowered.

Furthermore, with regard to a space between the field plate electrode 18b (second auxiliary electrode) and the n⁻ drift region 40 (third semiconductor region of second conductivity type), as shown in FIGS. 10 and 12, when the space along the Y direction (second direction) is assumed to be t1, and the space on the n⁺ drain region 12 (second semiconductor region of second conductivity type) side in the X direction (first direction) is assumed to be t2, t1<t2 is preferred.

Thereby, the effective impurity amount contained in n⁻ drift region 40 (third semiconductor region of second conductivity type) is allowed to increase toward the n⁺ drain region 12 (second semiconductor region of second conductivity type), causing the electric field reduction. This causes the breakdown voltage to be further increased.

In FIGS. 10, 12, the STI 17 (first insulating layer) is in contact with the n⁺ drain region 12 (second semiconductor region of second conductivity type), but the STI 17 (first insulating layer) may be formed so as to be in contact with the n⁺ drain region 12 (second semiconductor region of second conductivity type). In application to the case of the low drain current density, as described above, the STI 17 (first insulating layer) may be formed in contact with the n⁺ drain region 12 (second semiconductor region of second conductivity type).

Moreover, the STI 17 (first insulating layer) may be formed spaced from the n⁺ drain region 12 (second semiconductor region of second conductivity type). Thereby, the effective impurity amount contained in the n⁻ drift region 40 (third semiconductor region of second conductivity type) is large because of no STI 17 (first insulating layer) provided, and effective to the suppression of the Kirk effect.

Also in the semiconductor devices 52, 53, similar to the semiconductor device 51, the n⁻ drift region 40 (third semiconductor region of second conductivity type) can be provided between the gate electrode 16 (control electrode) and the STI 17 (first insulating layer). Thereby, in the all channels occurring immediately under the gate electrode 16 (control electrode), first, the current flows through the n⁻ drift region 40 (third semiconductor region of second conductivity type), and then flows into the n⁺ drain region 12 (second semiconductor region of second conductivity type) through the n⁻ drift region 40 (third semiconductor region of second conductivity type) between the STIs 17 (first insulating layer).

Thus, all channels operation is effective and On resistance is decreased.

### Sixth Embodiment

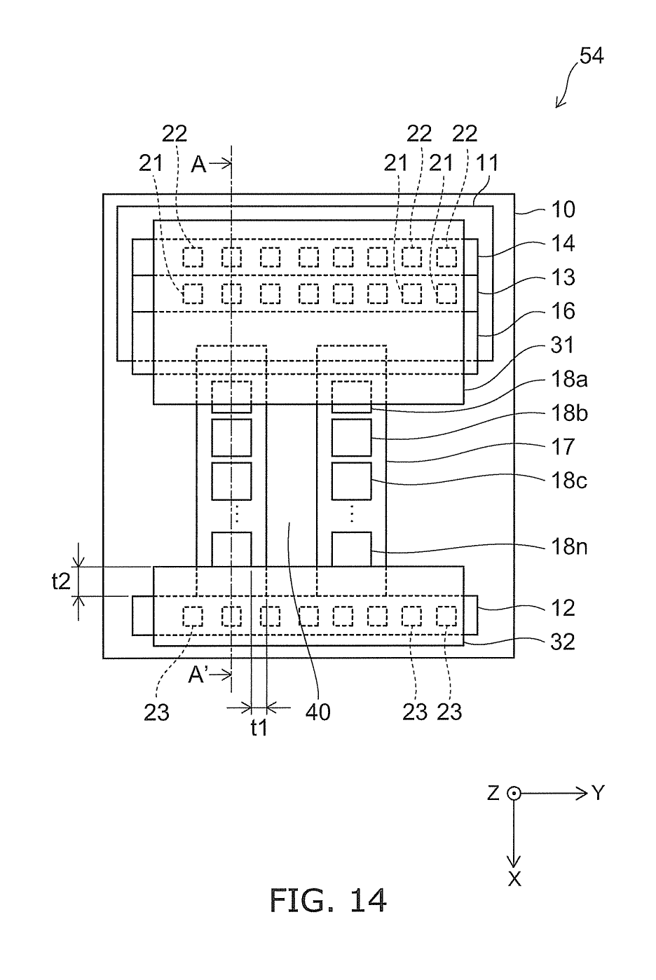

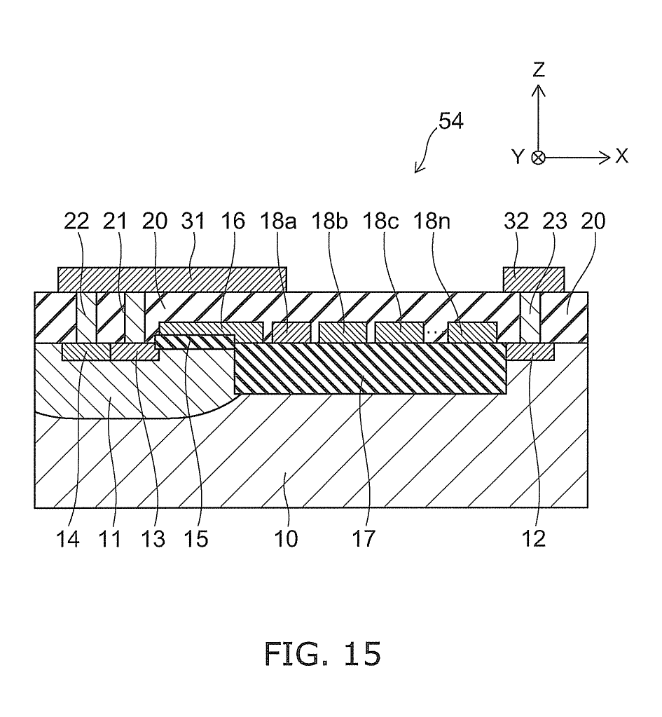

FIGS. 14 and 15 are schematic views illustrating the configuration of the schematic views according to a sixth embodiment of the invention.

FIG. 14 is a schematic plan view illustrating the configuration of the semiconductor according to the sixth embodiment of the invention.

FIG. 15 is a cross-sectional view along A-A′ line of the semiconductor device shown in FIG. 14.

As shown in FIGS. 14 and 15, a plane parallel to a major surface of a p-type semiconductor substrate 10 (semiconductor layer of first conductivity type) is set to be an X-Y plane, and a direction perpendicular to the X-Y plane is set to be a Z-axis. A direction of the A-A′ line shown in FIG. 14 is set to be an X-axis, and a direction perpendicular to the Z-axis and X-axis is set to be a Y-axis.

Here, in the plan view, a portion essentially unseen by an insulating layer is also shown with a solid line.

The semiconductor device 54 according to the sixth embodiment of the invention is MOSFET.

In the semiconductor device 54, a plurality of field plate electrodes 18a (first auxiliary electrode), 18b, 18c, 18n (second auxiliary electrode) are provided on each of the STIs 17 (first insulating layer). The rest other than this is the same as the semiconductor device 50, and hence the description is omitted.

Here, the example shows the case where four field plate electrodes 18a (first auxiliary electrode), 18b, 18c, 18n (second auxiliary electrode) exist on each of the STIs 17 (first insulating layer), however, the number of electrodes is not limited thereto. An integer number of one or more may be allowed. One field plate electrode 18a (first auxiliary electrode) electrically insulated may be provided.

In the semiconductor device 54 shown in FIGS. 14 and 15, the field plate electrode 18a (first auxiliary electrode), 18b, 18c, 18n (second auxiliary electrode) are insulated from all other electrodes. Therefore, potential of the field plate electrode 18a (first auxiliary electrode), 18b, 18c, 18n (second auxiliary electrode) is given by a voltage value defined by electrostatic capacitance between each of the source electrode 31 (first main electrode), the drain electrode 32 (second main electrode) and the gate electrode 16 (control electrode) and each of the field plate electrode 18a (first auxiliary electrode), 18b, 18c, 18n (second auxiliary electrode).

The potential of the field plate electrode 18a (first auxiliary electrode), 18b, 18c, 18n (second auxiliary electrode) gradually increase from the gate electrode 16 (control electrode) toward the drain electrode 32 (second main electrode). Thereby, in the OFF state, the potential of the n⁻ drift region 40 (third semiconductor region of second conductivity type) generates uniform electric field due to the effect of the potential of each of the field plate electrode 18a (first auxiliary electrode), 18b, 18c, 18n (second auxiliary electrode), and the breakdown voltage is increased.

The field plate electrode 18a (first auxiliary electrode), 18b, 18c, 18n (second auxiliary electrode) are not connected to the gate electrode 16 (control electrode), hence the capacitance between the gain and the drain and the capacitance between the gate and the source are reduced.

Here, when a plurality of field plate electrodes are provided, the field plate electrode 18a (first auxiliary electrode) can be electrically connected to the gate electrode 16 (control electrode). The field plate electrode 18a (first auxiliary electrode) has a shorter length in the Y direction than the STI 17 (first insulating layer), and the field plate electrodes 18b, 18c, 18n (second auxiliary electrode) are electrically insulated from the gate electrode 16 (control electrode), and thus the capacitance between the gate and the drain and the capacitance between the gate and the source are reduced as compared with the field effect transistor 150 of the comparative example.

The electrode closest to the drain electrode 32 (second main electrode) (field plate electrode 18n in FIGS. 14 and 15) among the field plate electrodes 18b, 18c, 18n (second auxiliary electrode) can be electrically connected to the drain electrode 32 (second main electrode). Similar to the semiconductor device 50, when the impurity concentration in the n⁻ drift region 40 (third semiconductor region of second conductivity type) is set to be low, the region 40 is depleted by low voltage in the OFF state. Then the electric field is concentrated at the end of the n⁺ drain region 12 (second semiconductor region of second conductivity type) having a shallow junction depth. The field plate electrode 18n (second auxiliary electrode) has the same potential as the drain electrode 32 (second main electrode), thereby the electric field at the end of the n⁺ drain region 12 (second semiconductor region of second conductivity type) is allowed to be reduced and the breakdown voltage is susceptible to be ensured.

The electrode closest to the drain electrode 32 (second main electrode) (field plate electrode 18n in FIGS. 14 and 15) among the field plate electrodes 18b, 18c, 18n (second auxiliary electrode) has a shorter length in the X direction than the STI 17 (first insulating layer), and the field plate electrodes 18a (first auxiliary electrode is electrically insulated from the gate electrode 16 (control electrode), and thus the capacitance between the gate and the drain and the capacitance between the gate and the source are reduced as compared with the field effect transistor 150 of the comparative example.

The field plate electrode 18a (first auxiliary electrode) is electrically connected to the gate electrode 16 (control electrode), and the electrode closest to the drain electrode 32 (second main electrode) (field plate electrode 18n in FIGS. 14 and 15) among the field plate electrodes 18b, 18c, 18n (second auxiliary electrode) can be electrically connected to the drain electrode 32 (second main electrode).

The electrode closest to the drain electrode 32 (second main electrode) (field plate electrode 18n in FIGS. 14 and 15) among field plate electrode 18a (first auxiliary electrode) and the field plate electrode 18b, 18c, 18n (second auxiliary electrode) has a shorter length in the X direction than the STI (first insulating layer), and the electrode except the electrode closest to the drain electrode 32 (second main electrode) among the field plate electrodes 18b, 18c (second auxiliary electrode) is electrically insulated from the gate electrode 16 (control electrode) and the drain electrode 32 (second main electrode), and thus the capacitance between the gate and the drain and the capacitance between the gate and the source are reduced as compared with the field effect transistor 150 of the comparative example.

Furthermore, also in the semiconductor device 54 of the example, similar to the semiconductor device 50, it is preferred that the width along the Y direction (second direction) of the STI 17 (first insulating layer) is narrowing toward the n⁺ drain region 12 (second semiconductor region of second conductivity type). It is preferred that the widths along the Y direction (second direction) of the field plate electrode 18a (first auxiliary electrode) and 18b, 18c, 18n (second auxiliary electrode) are narrowing toward the n⁺ drain region 12 (second semiconductor region of second conductivity type). When the widths along the Y direction (second direction) are not narrowing, for example, are constant, the gate electrode 16 (control electrode) side of the n⁻ drift region 40 (third semiconductor region of second conductivity type) is resistant to the depletion. Therefore, the electric field between the gate electrode 16 (control electrode) and the n⁻ drift region 40 (third semiconductor region of second conductivity type) increases and the breakdown voltage is lowered.

Furthermore, with regard to a space between the field plate electrode 18n (first auxiliary electrode) and the n⁻ drift region 40 (third semiconductor region of second conductivity type), as shown in FIG. 14, when the space along the Y direction (second direction) is assumed to be t1, and the space on the n⁺ drain region 12 (second semiconductor region of second conductivity type) side in the X direction (first direction) is assumed to be t2, t1<t2 is preferred.

Thereby, the effective impurity amount contained in n⁻ drift region 40 (third semiconductor region of second conductivity type) is allowed to increase toward the n⁺ drain region 12 (second semiconductor region of second conductivity type), causing the electric field reduction. This causes the breakdown voltage to be further increased.

In FIG. 14, the STI 17 (first insulating layer) is in contact with the n⁺ drain region 12 (second semiconductor region of second conductivity type), but the STI 17 (first insulating layer) may be formed so as to be in contact with the n⁺ drain region 12 (second semiconductor region of second conductivity type). In application to the case of the low drain current density, as described above, the STI 17 (first insulating layer) may be formed in contact with the n⁺ drain region 12 (second semiconductor region of second conductivity type).

Moreover, the STI 17 (first insulating layer) may be formed spaced from the n⁺ drain region 12 (second semiconductor region of second conductivity type). Thereby, the effective impurity amount contained in the n⁻ drift region 40 (third semiconductor region of second conductivity type) is large because of no STI 17 (first insulating layer) provided, and effective to the suppression of the Kirk effect.

Also in the semiconductor devices 54, similar to the semiconductor device 51, the n⁻ drift region 40 (third semiconductor region of second conductivity type) can be provided between the gate electrode 16 (control electrode) and the STI 17 (first insulating layer). Thereby, in the all channels occurring immediately under the gate electrode 16 (control electrode), first, the current flows through the n⁻ drift region 40 (third semiconductor region of second conductivity type), and then flows into the n⁺ drain region 12 (second semiconductor region of second conductivity type) through the n⁻ drift region 40 (third semiconductor region of second conductivity type) between the STIs 17 (first insulating layer).

Thus, all channels operation is effective and On resistance is decreased.

### Seventh Embodiment

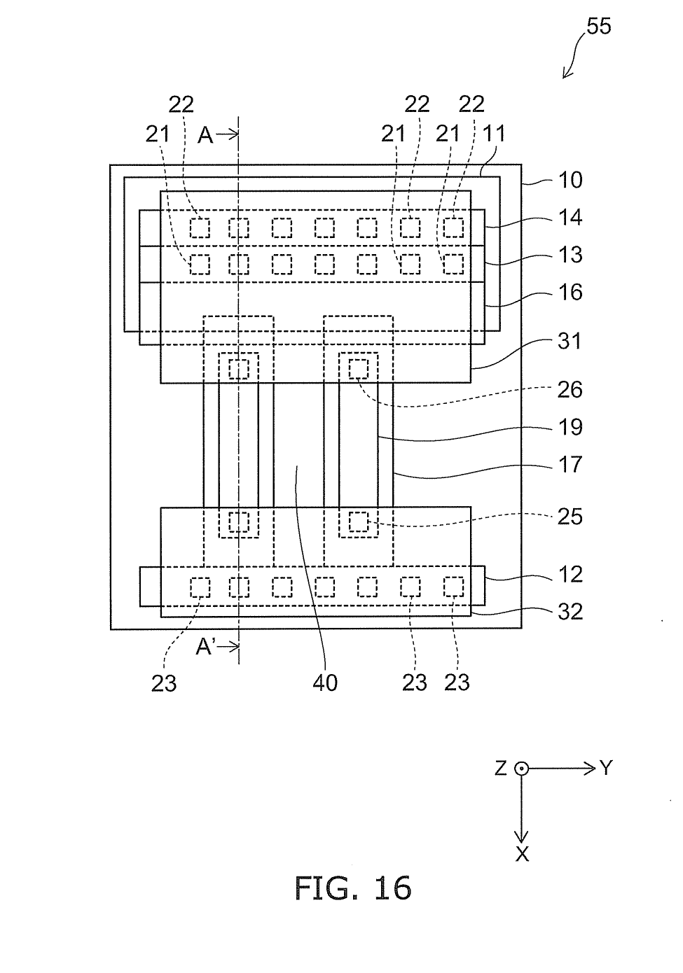

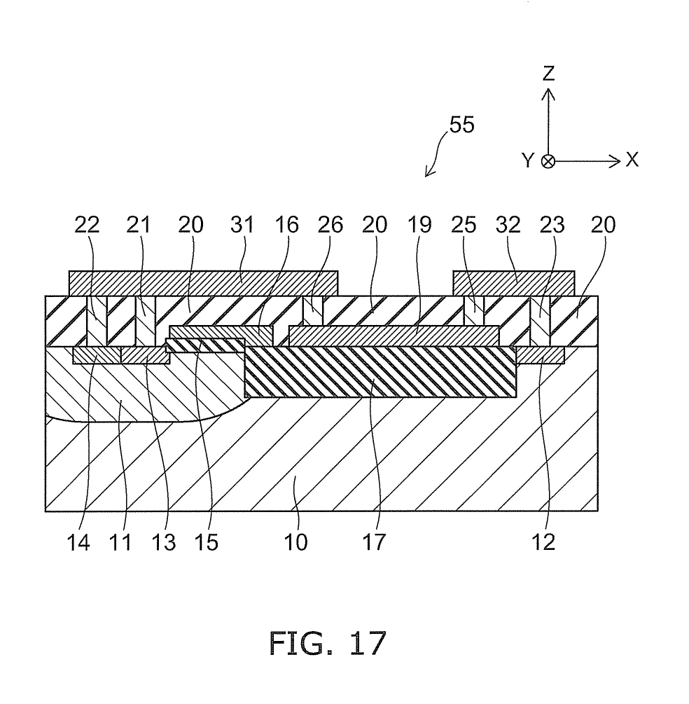

FIGS. 16 and 17 are schematic views illustrating the configuration of the semiconductor device according to a seventh embodiment of the invention.

FIG. 16 is a schematic plan view illustrating the semiconductor device according to the seventh embodiment of the invention.

FIG. 17 is a cross-sectional view along A-A′ line of the semiconductor device shown in FIG. 16.

As shown in FIGS. 16 and 17, a plane parallel to a major surface of a p-type semiconductor substrate 10 (semiconductor layer of first conductivity type) is set to be an X-Y plane, and a direction perpendicular to the X-Y plane is set to be a Z-axis. A direction of the A-A′ line shown in FIG. 16 is set to be an X-axis, and a direction perpendicular to the Z-axis and X-axis is set to be a Y-axis.

Here, in the plan view, a portion essentially unseen by an insulating layer is also shown with a solid line.

The semiconductor device 55 according to the seventh embodiment of the invention is MOSFET.

In the semiconductor device 55, a high resistance layer 19 is provided on each of the STIs 17 (first insulating layer). In the high resistance layer, one end close to the source electrode 31 (first main electrode) is connected to the source electrode 31 (first main electrode) via a via plug 26, and the other end close to the drain electrode 32 (second main electrode) is connected to the drain electrode 32 (second main electrode) via a via plug 25. The high resistance layer 19 is, for example, a SIPOS (Semi-Insulating Poly-crystalline Silicon) layer or a layer including the SIPOS layer. The rest other than this is the same as the semiconductor device 52, and hence the description is omitted.

In the semiconductor device 55 shown in FIGS. 16 and 17, both ends of the high resistance layer 19 are electrically connected to the source electrode 31 (first main electrode) and the drain electrode 32 (second main electrode). In the OFF state where voltage of threshold voltage or less is applied to the gate electrode 16 (control electrode), a potential difference is generated between the drain electrode 32 (second main electrode) and the source electrode 31 (first main electrode), a current flows through the high resistance layer 19 and a equipotential line with an equal space is produced at each position of the high resistance layer 19. Thereby, the electric field is relieved and the breakdown voltage is increased in the case where the n⁻ drift region 40 (third semiconductor region of second conductivity type) is depleted. The high resistance layer 19 is connected to the source electrode 31 (first main electrode) and the drain electrode 32 (second main electrode), hence the capacitance between the gate and the drain and the capacitance between the gate and the source are reduced.

Also in the semiconductor device 54 of the example, similar to the semiconductor device 50, it is preferred that the width along the Y direction (second direction) of the STI 17 (first insulating layer) is narrowing toward the n⁺ drain region 12 (second semiconductor region of second conductivity type). It is preferred that the width along the Y direction (second direction) of the high resistance layer 19 is narrowing toward the n⁺ drain region 12 (second semiconductor region of second conductivity type). When the widths along the Y direction (second direction) are not narrowing, for example, are constant, the gate electrode 16 (control electrode) side of the n⁻ drift region 40 (third semiconductor region of second conductivity type) is resistant to the depletion. Therefore, the electric field between the gate electrode 16 (control electrode) and the n⁻ drift region 40 (third semiconductor region of second conductivity type) increases and the breakdown voltage is lowered.

In FIG. 16, the STI 17 (first insulating layer) is in contact with the n⁺ drain region 12 (second semiconductor region of second conductivity type), but the STI 17 (first insulating layer) may be formed so as to be in contact with the n⁺ drain region 12 (second semiconductor region of second conductivity type). In application to the case of the low drain current density, as described above, the STI 17 (first insulating layer) may be formed in contact with the n⁺ drain region 12 (second semiconductor region of second conductivity type).

Moreover, the STI 17 (first insulating layer) may be formed spaced from the n⁺ drain region 12 (second semiconductor region of second conductivity type). Thereby, the effective impurity amount contained in the n⁻ drift region 40 (third semiconductor region of second conductivity type) is large because of no STI 17 (first insulating layer) provided, and effective to the suppression of the Kirk effect.

Also in the semiconductor devices 55, similar to the semiconductor device 51, the n⁻ drift region 40 (third semiconductor region of second conductivity type) can be provided between the gate electrode 16 (control electrode) and the STI 17 (first insulating layer). Thereby, in the all channels occurring immediately under the gate electrode 16 (control electrode), first, the current flows through the n⁻ drift region 40 (third semiconductor region of second conductivity type), and then flows into the n⁺ drain region 12 (second semiconductor region of second conductivity type) through the n⁻ drift region 40 (third semiconductor region of second conductivity type) between the STIs 17 (first insulating layer).

Thus, all channels operation is effective and On resistance is decreased.

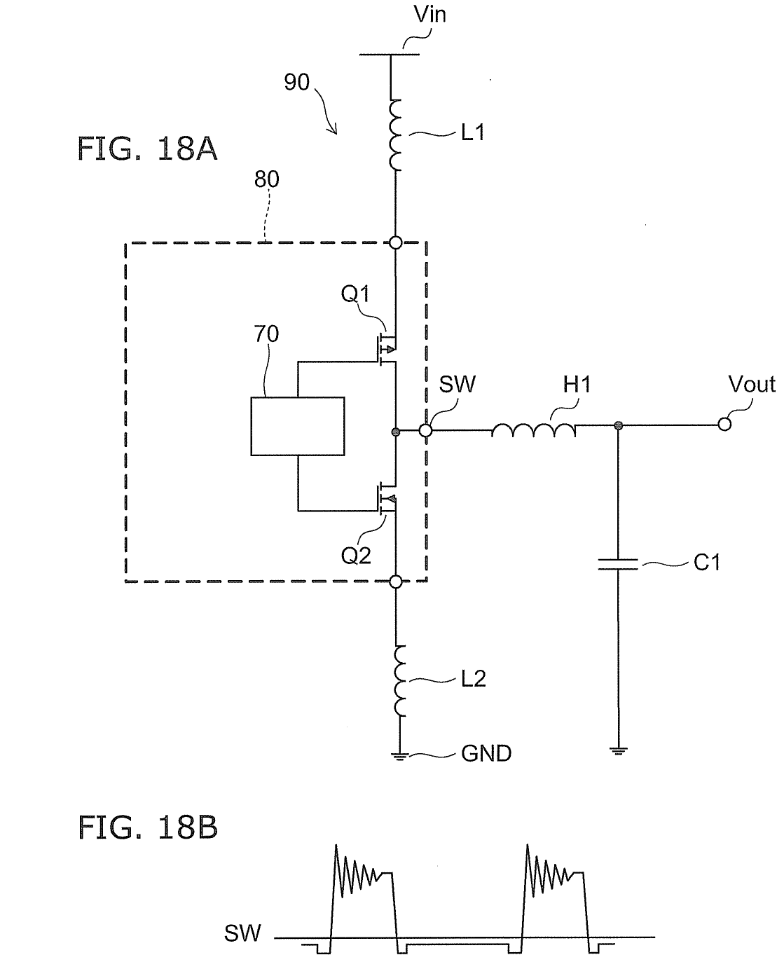

FIGS. 18A and 18B are schematic views of a switching power supply based on the semiconductor device of the invention.

FIG. 18A is a circuit diagram of the switching power supply in a mode of synchronous rectifying based on the semiconductor device of the invention. FIG. 18B shows a wave form of a drive terminal SW in the switching power supply shown in FIG. 18A.

As shown in FIG. 18A, a switching power supply 90 includes a semiconductor device 80 (part surrounded by a broken line in FIG. 18A), an inductor H1 and a capacitor C1.

The switching power supply 90 achieves output potential Vout from the drive terminal SW serving as an output terminal of the semiconductor device 80 through an output filter composed of the inductor H1 and the capacitor C1.

The semiconductor device 80 includes two series-connected switch elements Q1, Q2 and a control circuit 70, and is structured into one chip formed on the same substrate.

The semiconductor device shown in FIG. 18A is illustrated as the case where the switch element Q1 is P-type MOSFET and the switch element Q2 is N-type MOSFET. The switch element Q2 can be based on the MOSFET of the above semiconductor devices 50 to 55. The switch element Q1 is also constituted of the N-type MOSFET, and can be based on the MOSFET of the semiconductor devices 50 to 55.

In the semiconductor device 80, a connecting point of the two series-connected switch elements Q1, Q2 is connected to the drive terminal SW. Input potential Vin is applied to the drive terminal SW by turning on the switch element Q1. Reference potential GND is applied to the drive terminal SW by tuning on the switch element Q2. A square wave is outputted from the drive terminal SW by alternating exclusively tuning on and off of the switch elements Q1, Q2. The wave is smoothed through the output filter composed of the inductor H1 and the capacitor C1, and the direct-current output potential Vout is outputted.

The control circuit 70 inputs feedback of the output potential Vout (not shown), and controls the output potential Vout by controlling ON/OFF timing of the two switch elements Q1, Q2.

It has already been described that the switching loss is necessary to be reduced in order to raise a switching frequency of the power supply. Shortening of a switching time is effective to reduce the switching loss, and a change rate of a drain current I, di/dt, gets increased.

Small parasite inductance exists on the chip, but parasite inductance exists on a wire outside the chip, a package and a mount substrate. In particular, inductance of inductors L1, L2 existing on between the input potential Vin and the reference potential GND generate serge voltage of (parasite inductance)×di/dt on the drive terminal SW connected to the output filter composed of the inductor H1 and the capacitor C1.

FIG. 18B shows the waveform of the drive terminal SW. FIG. 18B shows the potential on the drive terminal SW, representing time by a horizontal axis. The oscillating waveform turns to be EMI noise and effects on peripheral circuits or peripheral devices.

It is known that placing an RC snubber between the drive terminal SW and the ground reduces the EMI noise of the drive terminal SW.

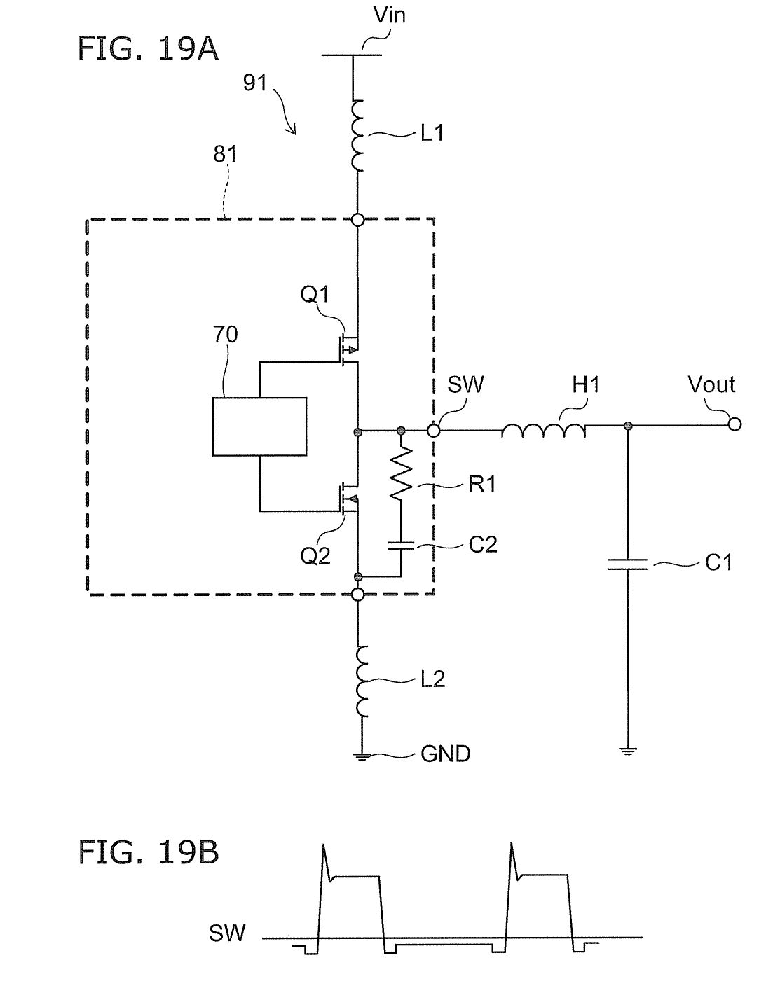

FIGS. 19A and 19B are schematic views of the switching power supply based on another semiconductor device if the invention.

FIG. 19A is a circuit diagram of the switching power supply based on the semiconductor device in a mode of synchronous rectifying, and FIG. 19B shows the waveform at the drive terminal SW of the switching power supply shown in FIG. 19A.

As shown in FIG. 19A, a switching power supply 91 includes a semiconductor device 81 (part surrounded by the broken line in FIG. 19A), the inductor H1 and the capacitor C1.

The semiconductor device 81 is different from the semiconductor device 80 in that the RC snubber including a resistor R1 and a capacitor C2 is formed between the drive terminal SW and the ground. The rest other than this is the same as the semiconductor device 80, and the description is omitted.

The RC snubber is usually attached externally.

In the example, the RC snubber is formed on the chip.

Next, an example where the RC snubber is formed on the chip is described.

### Eighth Embodiment

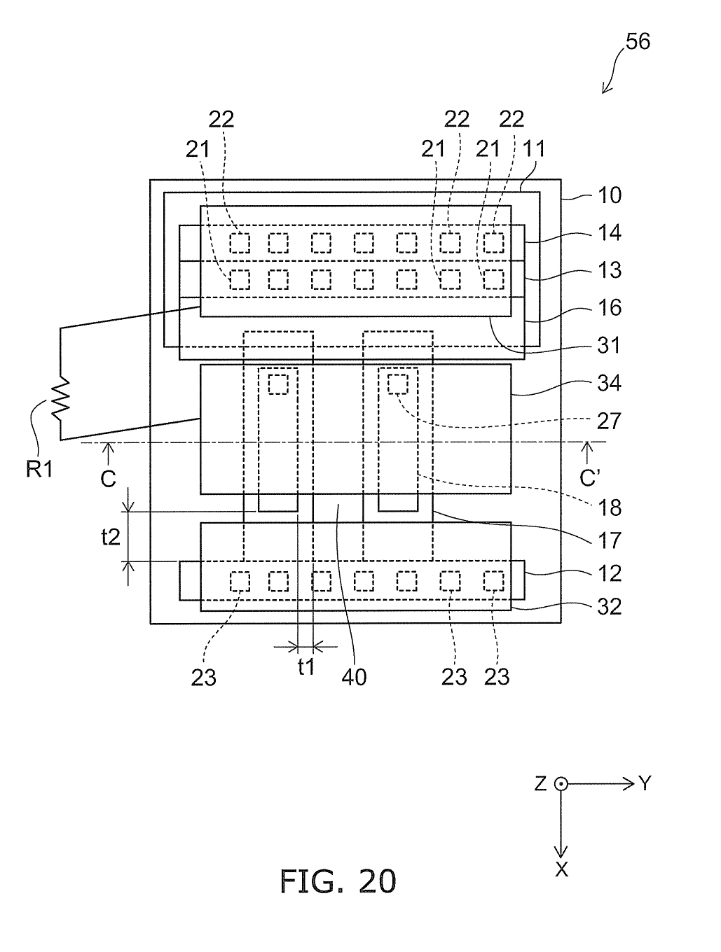

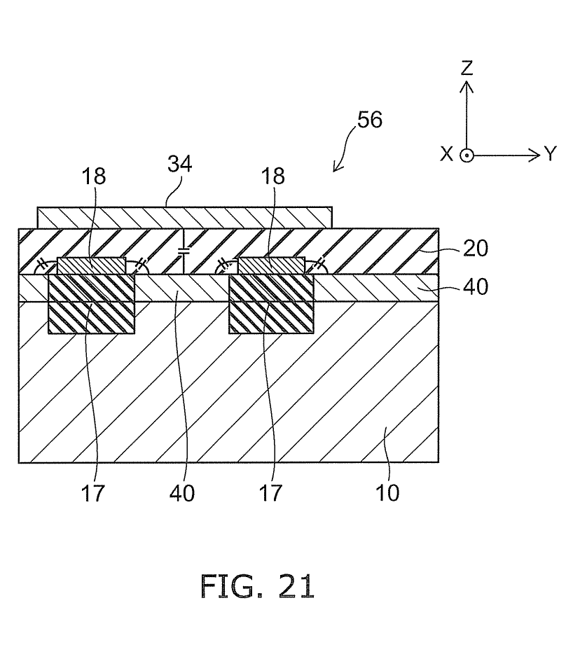

FIGS. 20 and 21 are schematic views illustrating the configuration of a semiconductor device according to a eighth embodiment of the invention.

FIG. 20 is a schematic plan view illustrating the configuration of the semiconductor device according to the eighth embodiment of the invention.

FIG. 21 is a cross-sectional view along C-C′ line of the semiconductor device shown in FIG. 20.

As shown in FIG. 20, in a semiconductor device 56, the field plate electrode 18 (first auxiliary electrode) is electrically connected to an electrode 34 via a via plug 27. The resistor R1 is placed between the electrode 34 and the source electrode 31 (first main electrode). The rest other than this is the same as the semiconductor device 50, and the description is omitted.

As shown in FIG. 20, the resistor R1 is placed between the field plate electrode 18 (first auxiliary electrode) and the source electrode 31 (first main electrode).

The field plate electrode 18 (first auxiliary electrode) enhances the depletion of the n⁻ drift region 40 (third semiconductor region of second conductivity type), hence the electric field occurs between the field plate electrode 18 (first auxiliary electrode) and the n⁻ drift region 40 (third semiconductor region of second conductivity type) to form the capacitance between the gate and the source. The RC snubber is constituted from placing the resistor R1 between the field plate electrode 18 (first auxiliary electrode) and the source electrode 31 (first main electrode).

The resistor R1 can be made of a resistor having impurity diffused into silicon or a resistor formed from a diffusion layer.

Thereby, the EMI noise can be suppressed without attachment of the RC snubber to the drive terminal SW as an external terminal.

Furthermore, also in the semiconductor device 56 of the example, similar to the semiconductor device 50, it is preferred that the width along the Y direction (second direction) of the STI 17 (first insulating layer) is narrowing toward the n⁺ drain region 12 (second semiconductor region of second conductivity type). It is preferred that the width along the Y direction (second direction) of the field plate electrode 18 (first auxiliary electrode) is narrowing toward the n⁺ drain region 12 (second semiconductor region of second conductivity type). When the width along the Y direction (second direction) is not narrowing, for example, is constant, the gate electrode 16 (control electrode) side of the n⁻ drift region 40 (third semiconductor region of second conductivity type) is resistant to the depletion. Therefore, the electric field between the gate electrode 16 (control electrode) and the n⁻ drift region 40 (third semiconductor region of second conductivity type) increases and the breakdown voltage is lowered.

Furthermore, with regard to a space between the field plate electrode 18 (second auxiliary electrode) and the n⁻ drift region 40 (third semiconductor region of second conductivity type), as shown in FIG. 20, when the space along the Y direction (second direction) is assumed to be t1, and the space on the n⁺ drain region 12 (second semiconductor region of second conductivity type) side in the X direction (first direction) is assumed to be t2, t1<t2 is preferred.

Thereby, the effective impurity amount contained in n⁻ drift region 40 (third semiconductor region of second conductivity type) is allowed to increase toward the n⁺ drain region 12 (second semiconductor region of second conductivity type), causing the electric field reduction. This causes the breakdown voltage to be further increased.

Also in the semiconductor devices 56, similar to the semiconductor device 51, the n⁻ drift region 40 (third semiconductor region of second conductivity type) can be provided between the gate electrode 16 (control electrode) and the STI 17 (first insulating layer). Thereby, in the all channels occurring immediately under the gate electrode 16 (control electrode), first, the current flows through the n⁻ drift region 40 (third semiconductor region of second conductivity type), and then flows into the n⁺ drain region 12 (second semiconductor region of second conductivity type) through the n⁻ drift region 40 (third semiconductor region of second conductivity type) between the STIs 17 (first insulating layer).

Thus, all channels operation is effective and On resistance is decreased.

Also in the semiconductor devices 52 to 54 mentioned above, similar to the example, the RC snubber is constituted from placing the resistor R1 between each of the field plate electrodes 18a (first auxiliary electrode), 18b, 18c, 18n (second auxiliary electrode) and the source electrode 31 (first main electrode).

### Ninth Embodiment

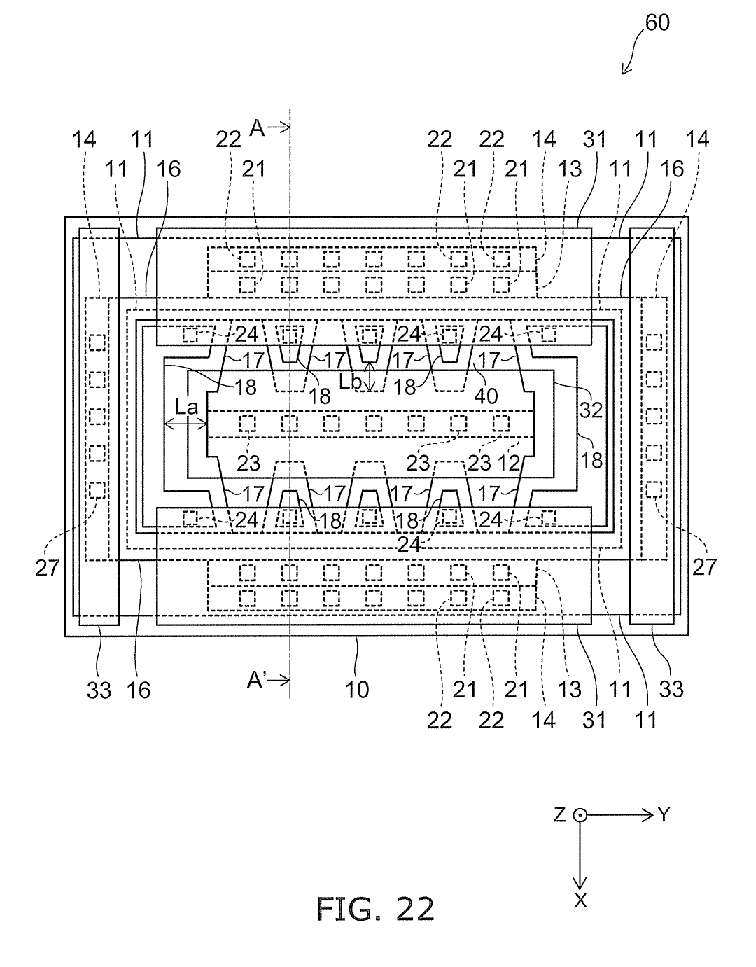

FIG. 22 is a schematic plan view illustrating the configuration of a semiconductor device according to an ninth embodiment of the invention.

As shown in FIG. 22, a plane parallel to a major surface of a p-type semiconductor substrate 10 (semiconductor layer of first conductivity type) is set to be an X-Y plane, and a direction perpendicular to the X-Y plane is set to be a Z-axis. A direction of the A-A′ line shown in FIG. 22 is set to be an X-axis, and a direction perpendicular to the Z-axis and X-axis is set to be a Y-axis.

Here, in the plan view, a portion essentially unseen by an insulating layer is also shown with a solid line.

The semiconductor device 60 shown in FIG. 22 is MOSFET.

A cross-sectional view along line A-A′ of the semiconductor device 60 is symmetrical. The left half is the same as the cross-sectional view along A-A′ line of the semiconductor device 50 shown in FIG. 2.

The STI 17 (first insulating layer) completely fills between the n⁺ drain region 12 (second semiconductor region of second conductivity type) and the field plate electrode 18 (first auxiliary electrode) at both ends in the Y direction. The gate electrode 16 (control electrode) electrically insulated from the field plate electrode 18 (first auxiliary electrode) is provided and ends at the p⁺ contact region 14.

The p⁺ contact region 14 is connected to an electrode 33 via the via plug 26.

The semiconductor device 60 has the configuration such that a plurality of the semiconductor devices 50 are disposed symmetrically to the Y axis in common with the n⁺ drain region 12 (second semiconductor region of second conductivity type). The n⁺ drain region 12 (second semiconductor region of second conductivity type) is surrounded by the gate electrode 16 (control electrode), furthermore is surrounded by the n⁻ source region 13.

The field strength gets increased at an end portion in the Y direction perpendicular to the X direction of the current flow, and causes reduction of the breakdown voltage. Thus, the end portion in the Y direction between the n⁺ drain region 12 (second semiconductor region of second conductivity type) and the field plate electrode 18 (first auxiliary electrode) is filled completely with the STI 17 (first insulating layer).

A length La between the n⁺ drain region 12 (second semiconductor region of second conductivity type) and the field plate electrode 18 (first auxiliary electrode) is set to be longer than a length Lb of a region of current flowing between the n⁺ drain region 12 (second semiconductor region of second conductivity type) and the field plate electrode 18 (first auxiliary electrode).

An electric field concentration point is placed at a center of the element, hence an avalanche current is flown through the whole element at avalanche breakdown, and thus avalanche withstand capability can be improved under an inductance load and at switching where the inductor is not clamped. The reason is as follows. When the electric field is concentrated only at the end portion, the large avalanche current flows through the narrow region and the breakdown tends to occur.

As described above, the semiconductor device 60 can reduce the capacitance between the gate and the drain and the capacitance between the gate and the source without additional processes.

The semiconductor device 60 has the configuration such that a plurality of the semiconductor devices 50 are disposed symmetrically to the Y direction in common with the drain electrode 32 (second main electrode), however the configuration of disposing a plurality of other semiconductor devices 51 to 56 is also possible.

A plurality of the semiconductor devices 50 to 56 can also be disposed symmetrically to the Y direction in common with the n⁺ source region 13 (first semiconductor region of second conductivity type). Specifically, the n⁺ source region 13 (first semiconductor region of second conductivity type) disposed at a center can also be surrounded by the gate electrode 16 (control electrode), furthermore is surrounded by the n⁺ drain region 12 (second semiconductor region of second conductivity type).

A plurality of the semiconductor devices 60 are formed on the p-type semiconductor substrate 10 (semiconductor layer of first conductivity type) and are connected in parallel. This allows also a larger current to be flowed.

Furthermore, from a viewpoint of a power device, the semiconductor devices 50 to 56, 60 are formed on the same substrate as other CMOS elements like as the semiconductor devices 80, 81, thereby more complex systems and more intelligent power devices can be planned.

In the above, the first conductivity type is set to be p-type and the second conductivity type is set to be n-type, however these are mutually exchangeable. Specifically, the first conductivity type may be n-type and the second conductivity type may be p-type. For example, the first conductivity type region may be the n well layer, the first second conductivity type layer may be the p⁺ source region, the second second conductivity type layer may be the p⁺ drain region, and the p− source region may be the third second conductivity type layer. The high resistance layer 19 only needs to be illustratively the SIPOS layer or the layer including the SIPOS layer.

The embodiment of the invention has been described with reference to specific examples. However, the invention is not limited to these specific examples. For instance, the specific configurations of the components constituting the semiconductor device can be suitably selected from conventional ones by those skilled in the art, and such configurations are encompassed within the scope of the invention as long as they can also implement the invention and achieve similar effects.

Components in two or more of the specific examples can be combined with each other as long as technically feasible, and such combinations are also encompassed within the scope of the invention as long as they fall within the spirit of the invention.

The semiconductor devices described above as the embodiment of the invention can be suitably modified and practiced by those skilled in the art, and such modifications are also encompassed within the scope of the invention as long as they fall within the spirit of the invention.

Various other variations and modifications can be conceived by those skilled in the art within the spirit of the invention, and it is understood that such variations and modifications are also encompassed within the scope of the invention.

1. A semiconductor device comprising:
a semiconductor region of first conductivity type provided in a semiconductor layer of first conductivity type;
a first semiconductor region of second conductivity type provided in the semiconductor region of first conductivity type;
a second semiconductor region of second conductivity type provided in the semiconductor layer of first conductivity type spaced from the semiconductor region of first conductivity type;
a third semiconductor region of second conductivity type provided between the semiconductor region of first conductivity type and the second semiconductor region of second conductivity type in the semiconductor layer of first conductivity type, and having a lower impurity concentration than the second semiconductor region of second conductivity type;
a first insulating layer provided in the third semiconductor region of second conductivity type;
a control electrode provided on the semiconductor region of first conductivity type arranged between the first semiconductor region of second conductivity type and the third semiconductor region of second conductivity type via a second insulating layer;
a first auxiliary electrode provided on the first insulating layer spaced from the control electrode;
a first main electrode electrically connected to the first semiconductor region of second conductivity type; and
a second main electrode electrically connected to the second semiconductor region of second conductivity type,
when a direction substantially parallel to a direction of a main current flowing between the first semiconductor region of second conductivity type and the second semiconductor region of second conductivity type being defined as a first direction, and
a direction substantially perpendicular to the first direction and substantially parallel to a major surface of the semiconductor layer of first conductivity type being defined as a second direction,
most part of the first insulating layer having a width along the second direction substantially narrowing from the control electrode toward the second main electrode.

2. The device according to claim 1, wherein the first insulating layer is provided through the third semiconductor region of second conductivity type to reach the semiconductor layer of first conductivity type.

3. The device according to claim 1, wherein the first auxiliary electrode has a width along the second direction substantially narrowing from the control electrode toward the second main electrode, and is electrically connected to the first main electrode.

4. The device according to claim 1, wherein a space along the first direction between the first auxiliary electrode and the first insulating layer is larger than a space along the second direction between the first auxiliary electrode and the first insulating layer.

5. The device according to claim 1, wherein the first insulating layer and the first auxiliary electrode are formed in a striped configuration in the second direction.

6. The device according to claim 1, wherein the third semiconductor region of second conductivity type is provided between the first insulating layer and the control electrode.

7. The device according to claim 1, wherein the first insulating layer is in contact with the second semiconductor region of second conductivity type.

8. The device according to claim 1, wherein the third semiconductor region of second conductivity type is provided between the first insulating layer and the second semiconductor region of second conductivity type.

9. The device according to claim 1, further comprising a resistance layer provided on the semiconductor layer of first conductivity type, the resistance layer having one end electrically connected to the first auxiliary electrode, and having the other end electrically connected to the first main electrode.

10. A semiconductor device comprising:
a semiconductor region of first conductivity type provided in a semiconductor layer of first conductivity type;
a first semiconductor region of second conductivity type provided in the semiconductor region of first conductivity type;
a second semiconductor region of second conductivity type provided in the semiconductor layer of first conductivity type spaced from the semiconductor region of first conductivity type;
a third semiconductor region of second conductivity type provided between the semiconductor region of first conductivity type and the second semiconductor region of second conductivity type in the semiconductor layer of first conductivity type, and having a lower impurity concentration than the second semiconductor region of second conductivity type;
a first insulating layer provided in the third semiconductor region of second conductivity type;
a control electrode provided on the semiconductor region of first conductivity type arranged between the first semiconductor region of second conductivity type and the third semiconductor region of second conductivity type via a second insulating layer;
a first auxiliary electrode provided on the first insulating layer spaced from the control electrode;
at least one second auxiliary electrode provided on the first insulating layer spaced from the first auxiliary electrode;
a first main electrode electrically connected to the first semiconductor region of second conductivity type; and
a second main electrode electrically connected to the second semiconductor region of second conductivity type.

11. The device according to claim 10, wherein the first insulating layer is provided through the third semiconductor region of second conductivity type to reach the semiconductor layer of first conductivity type.

12. The device according to claim 10, wherein the first auxiliary electrode is electrically connected to the first main electrode.

13. The device according to claim 10, wherein
when a direction substantially parallel to a direction of a main current flowing between the first semiconductor region of second conductivity type and the second semiconductor region of second conductivity type being defined as a first direction, and
a direction substantially perpendicular to the first direction and substantially parallel to a major surface of the semiconductor layer of first conductivity type being defined as a second direction,
most part of the first insulating layer has a width along the second direction substantially narrowing from the control electrode toward the second main electrode.

14. The device according to claim 13, wherein a space along the first direction between the second auxiliary electrode and the first insulating layer is larger than a space along the second direction between the second auxiliary electrode and the first insulating layer.

15. The device according to claim 13, wherein the first insulating layer, the first auxiliary electrode and the second auxiliary electrode are formed in a striped configuration in the second direction.

16. The device according to claim 10, wherein the third semiconductor region of second conductivity type is provided between the first insulating layer and the control electrode.

17. The device according to claim 10, wherein the first auxiliary electrode is electrically connected to the control electrode.

18. The device according to claim 10, wherein the second auxiliary electrode is electrically connected to the second main electrode.

19. The device according to claim 10, wherein the electrode closest to the second main electrode among the second auxiliary electrodes is electrically connected to the second main electrode.

20. The device according to claim 13, wherein the second auxiliary electrode has a width along the second direction substantially narrowing from the control electrode toward the second main electrode.
